(19) United States
(12) Patent Application Publication
(10) Pub. No.: US 2023/0014689 A1
(43) Pub. Date: Jan. 19, 2023

(54) DETERIORATION DEGREE DIAGNOSIS DEVICE

(71) Applicant: Mitsubishi Electric Corporation, Tokyo (JP)

(72) Inventors: Keisuke OGASAWARA, Tokyo (JP); Tomoki TAKEGAMI, Tokyo (JP)

(73) Assignee: Mitsubishi Electric Corporation, Tokyo (JP)

(21) Appl. No.: 17/786,572

(22) PCT Filed: Mar. 10, 2020
(86) PCT No.: PCT/JP2020/010358

§ 371 Date: Jun. 17, 2022

(51) Int. Cl. G01R 31/392; G01R 31/385; H01M 10/48

(52) U.S. Cl. CPC G01R 31/392; G01R 31/385; H01M 10/486; G01R 31/374

(57) ABSTRACT

A deterioration degree diagnosis device includes: a charging/discharging control unit configured to control charging or discharging of a battery; a battery information measurement unit configured to measure a voltage and a current of the battery and measure a capacity and voltage transition during charging or discharging; a multiple data integration unit configured to integrate battery capacity voltage data in at least two different sections measured by the battery information measurement unit, and create a battery capacity voltage curve; and a deterioration degree diagnosis unit configured to estimate a deterioration degree of the battery on the basis of the battery capacity voltage curve.

### TECHNICAL FIELD

The present disclosure relates to a deterioration degree diagnosis device.

### BACKGROUND ART

The technology for estimating a deterioration degree of a battery is important in order to determine an appropriate replacement time of the battery and to accurately grasp the capacity of the battery in operation.

A method is disclosed in which a present open circuit voltage curve of a battery is estimated by recording a voltage curve in a specific section of the battery and repeatedly shifting and/or scaling positive electrode and negative electrode voltage curves, which are open circuit voltage curves, such that the electrode voltage curves match the voltage curve (actual measured value) in the specific section (for example, Patent Document 1).

Also, a battery control device is disclosed which measures an open circuit voltage curve of a battery, calculates deterioration parameters indicating positive electrode and negative electrode capacity retention rates and a deviation capacity corresponding to the positive and negative electrode compositions, from a running history, and repeatedly performs calculation such that an open circuit voltage curve (estimated value) matches an open circuit voltage curve (actual measured value), thereby specifying the open circuit voltage curve (estimated value) (for example, Patent Document 2).

### CITATION LIST

### Patent Document

Patent Document 1: Japanese Laid-Open Patent Publication (translation of PCT application) No. 2018-524602
Patent Document 2: Japanese Laid-Open Patent Publication No. 2017-195727

### SUMMARY OF THE INVENTION

### Problems to be Solved by the Invention

In an electric vehicle, a charging operation is a user-arbitrary operation, and an on-vehicle charger has a small battery capacity and takes time for full charging. Therefore, it is necessary to collect partial charging data in various sections of a battery by the on-vehicle charger, create a voltage curve using these data, analyze the voltage curve, and diagnose a deterioration degree of the battery. However, each of the method and the device of Patent Documents 1 and 2 does not have a function of creating a voltage curve using multiple data.

The present disclosure has been made to solve the above problem, and an object of the present disclosure is to provide a deterioration degree diagnosis device capable of accurately estimating a deterioration degree of a battery even when a charging operation as in an electric vehicle is a user-arbitrary operation.

### Solution to the Problems

A deterioration degree diagnosis device according to the present disclosure includes a charging/discharging control unit configured to control charging or discharging of a battery; a battery information measurement unit configured to measure a voltage and a current of the battery and measure a capacity and voltage transition during charging or discharging; a multiple data integration unit configured to integrate battery capacity voltage data in at least two different sections measured by the battery information measurement unit, and create a battery capacity voltage curve; and a deterioration degree diagnosis unit configured to estimate a deterioration degree of the battery on the basis of the battery capacity voltage curve.

### Effect of the Invention

With the deterioration degree diagnosis device according to the present disclosure, it is possible to accurately estimate a deterioration degree of a battery even when a charging operation as in an electric vehicle is a user-arbitrary operation.

### BRIEF DESCRIPTION OF THE DRAWINGS

FIG. 1 is a configuration diagram of a deterioration degree diagnosis device according to Embodiment 1.

FIG. 2 illustrates a relationship between the voltage of a battery, the potential of a positive electrode, and the potential of a negative electrode in the deterioration degree diagnosis device according to Embodiment 1

FIG. 3 illustrates a relationship between the voltage of the battery, the potential of the positive electrode, and the potential of the negative electrode at the time of positive electrode deterioration of the battery in the deterioration degree diagnosis device according to Embodiment 1.

FIG. 4 illustrates a relationship between the voltage of the battery, the potential of the positive electrode, and the potential of the negative electrode at the time of negative electrode deterioration of the battery in the deterioration degree diagnosis device according to Embodiment 1.

FIG. 5 illustrates a relationship between the voltage of the battery, the potential of the positive electrode, and the potential of the negative electrode at the time of Li ion consumption deterioration of the battery in the deterioration degree diagnosis device according to Embodiment 1.

FIG. 6 shows capacity derivative curves of the voltage of the battery, the potential of the positive electrode, and the potential of the negative electrode in the deterioration degree diagnosis device according to Embodiment 1.

FIG. 7 is a configuration diagram of a multiple data integration unit in the deterioration degree diagnosis device according to Embodiment 1.

FIG. 8 is a processing flowchart of the multiple data integration unit in the deterioration degree diagnosis device according to Embodiment 1.

FIG. 9 illustrates peak positions appearing in voltage capacity derivative curves in the deterioration degree diagnosis device according to Embodiment 1.

FIG. 10A illustrates change of a positive electrode peak position and a negative electrode peak position appearing in the voltage capacity derivative curves in the deterioration degree diagnosis device according to Embodiment 1.

FIG. 10B illustrates change of the positive electrode peak position and the negative electrode peak position appearing in the voltage capacity derivative curves in the deterioration degree diagnosis device according to Embodiment 1.

FIG. 11 illustrates an example of deterioration degree diagnosis based on dV/dQ curves of the negative electrode and the positive electrode in the deterioration degree diagnosis device according to Embodiment 1.

FIG. 12 illustrates an example of deterioration degree diagnosis based on the dV/dQ curves of the negative electrode and the positive electrode in the deterioration degree diagnosis device according to Embodiment 1.

FIG. 13 is a configuration diagram of a deterioration degree diagnosis device according to Embodiment 2.

FIG. 14 illustrates a correlation between the internal resistance and the temperature of a battery in the deterioration degree diagnosis device according to Embodiment 2.

FIG. 15 is a configuration diagram of an application example of the deterioration degree diagnosis device according to Embodiment 2.

FIG. 16 illustrates a reaction distribution model of an electrode in the deterioration degree diagnosis device according to Embodiment 2.

FIG. 17 is a configuration diagram of a deterioration degree diagnosis device according to Embodiment 3.

FIG. 18 illustrates a hysteresis phenomenon of a battery in the deterioration degree diagnosis device according to Embodiment 3.

FIG. 19A illustrates peak positions appearing in voltage capacity derivative curves when a hysteresis occurs in the deterioration degree diagnosis device according to Embodiment 3.

FIG. 19B illustrates peak positions appearing in voltage capacity derivative curves when a hysteresis occurs in the deterioration degree diagnosis device according to Embodiment 3.

FIG. 20 is a configuration diagram of a deterioration degree diagnosis device according to Embodiment 4.

FIG. 21 illustrates a correlation between a storage deterioration pattern and the temperature of a battery in the deterioration degree diagnosis device according to Embodiment 4.

FIG. 22 illustrates a correlation between a cycle deterioration pattern and the temperature of the battery in the deterioration degree diagnosis device according to Embodiment 4.

FIG. 23 is a configuration diagram of a deterioration degree diagnosis device according to Embodiment 5.

FIG. 24 is a configuration diagram when dedicated hardware is used to realize the functions of the deterioration degree diagnosis devices according to Embodiment 1 to Embodiment 5.

FIG. 25 is a configuration diagram when general-purpose hardware is used to realize the functions of the deterioration degree diagnosis devices according to Embodiment 1 to Embodiment 5.

### DESCRIPTION OF EMBODIMENTS

### Embodiment 1

Embodiment 1 relates to a deterioration degree diagnosis device including a charging/discharging control unit configured to control charging or discharging of a battery; a battery information measurement unit configured to measure a voltage and a current of the battery and measure a battery capacity and voltage transition during charging or discharging; a multiple data integration unit configured to integrate battery capacity voltage data in at least two different sections measured by the battery information measurement unit, and create a battery capacity voltage curve; and a deterioration degree diagnosis unit configured to estimate a deterioration degree of the battery on the basis of the battery capacity voltage curve, wherein the deterioration degree diagnosis unit analyzes a derivative curve of the battery capacity voltage curve, identifies deterioration factors based on a positive electrode, a negative electrode, and Li ion consumption, and estimates the deterioration degree of the battery.)

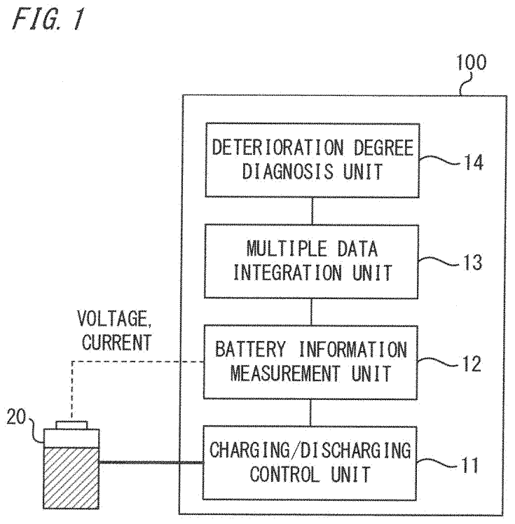

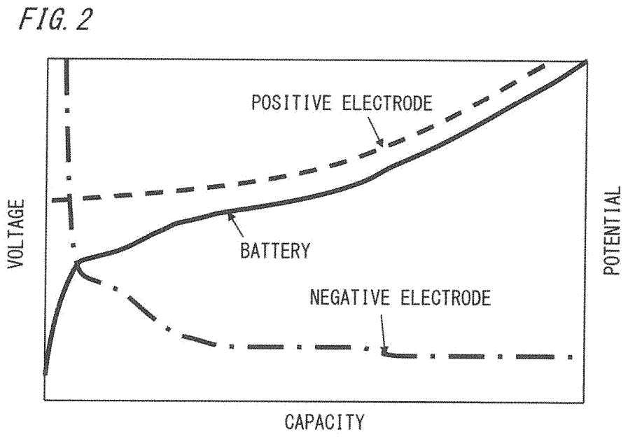

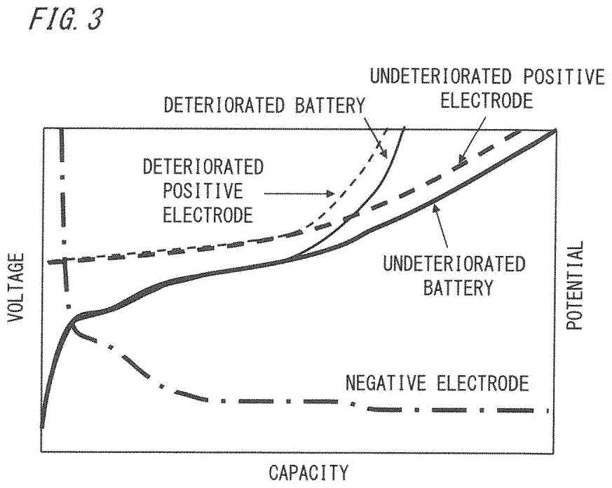

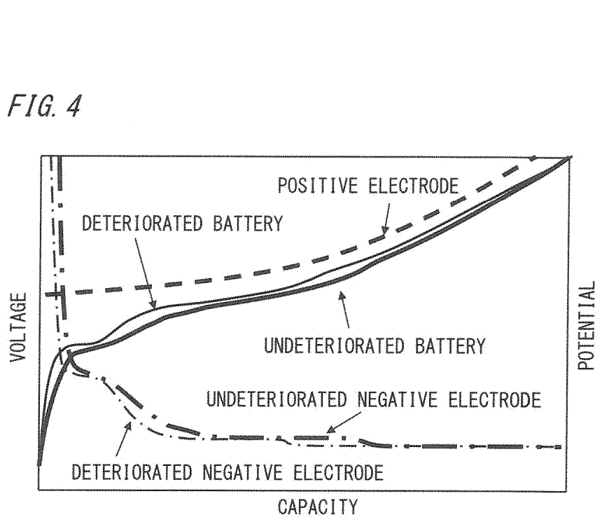

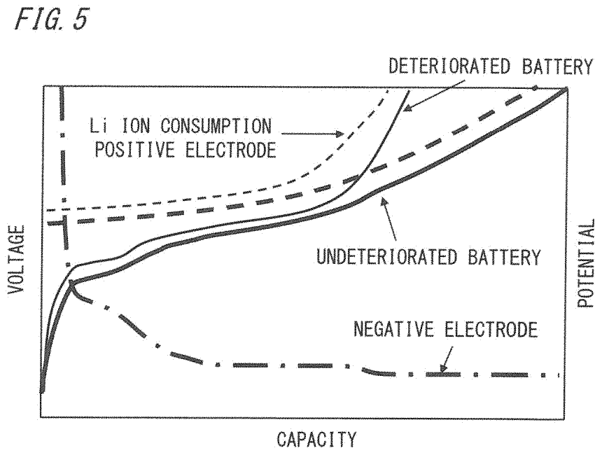

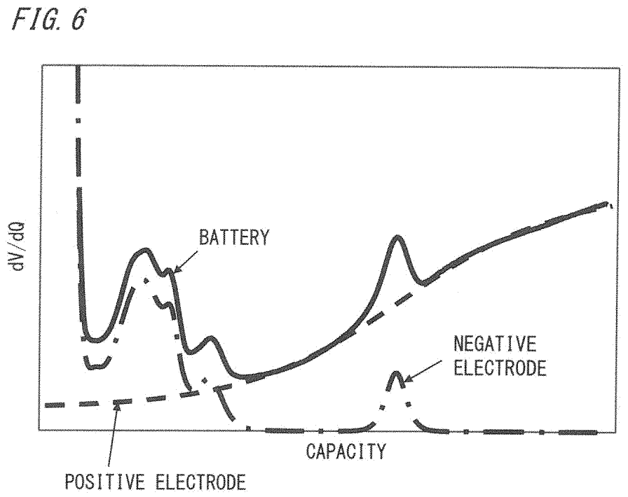

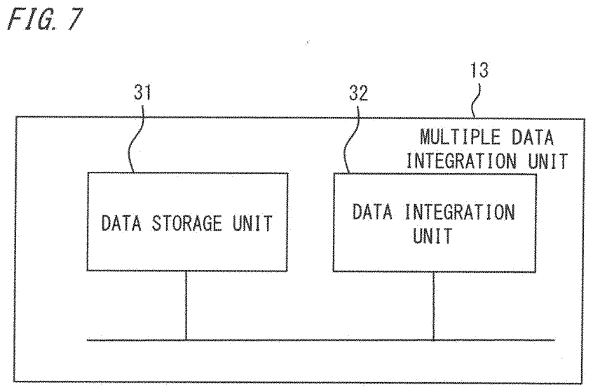

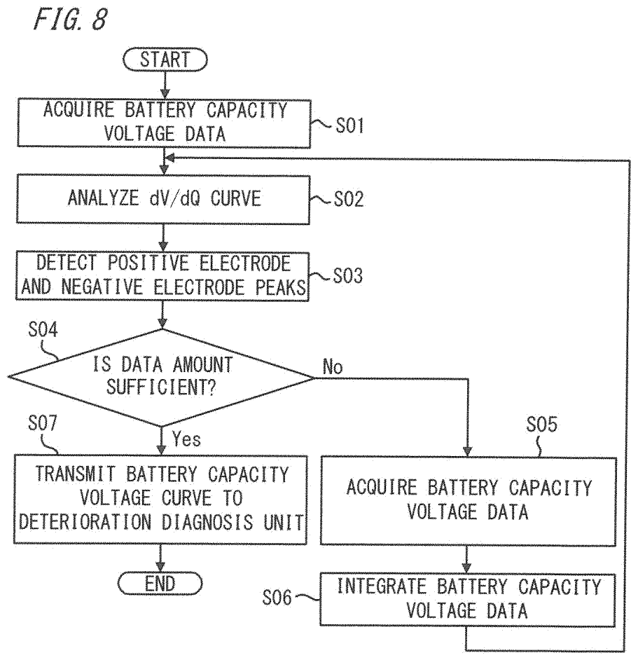

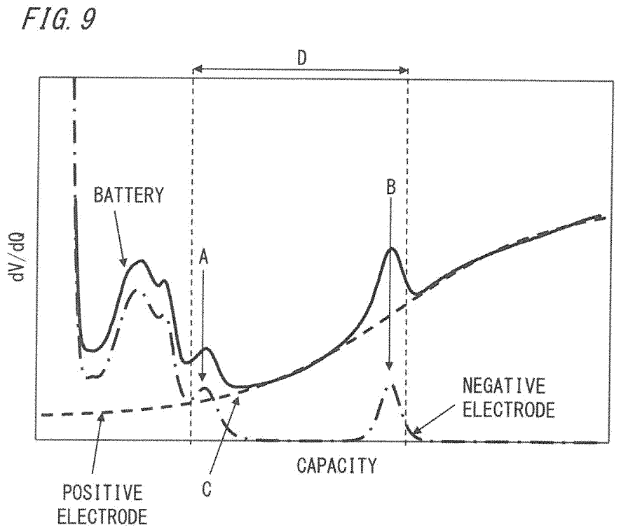

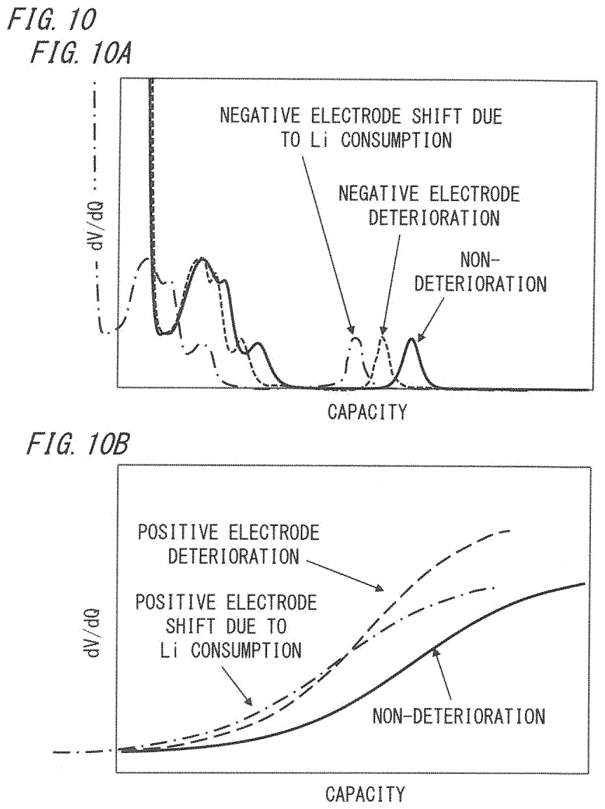

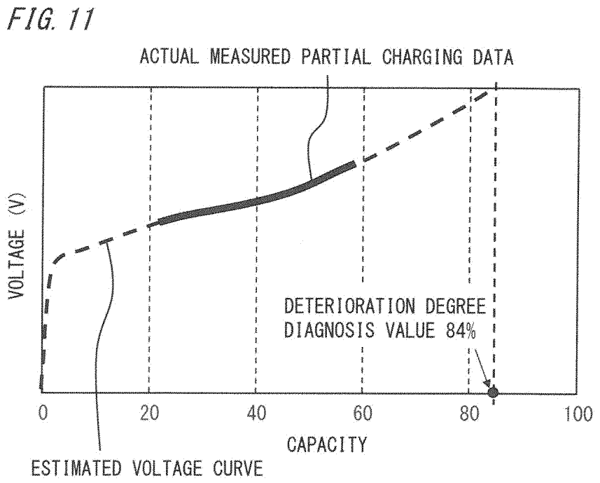

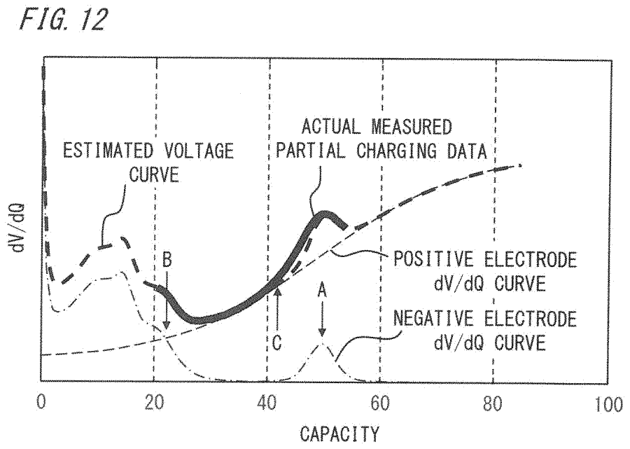

Hereinafter, the configuration and operation of a deterioration degree diagnosis device according to Embodiment 1 will be described with reference to FIG. 1 which is a configuration diagram of the deterioration degree diagnosis device, FIG. 2 which illustrates a relationship between the voltage of a battery, the potential of a positive electrode, and the potential of a negative electrode, FIG. 3 which illustrates a relationship between the voltage of the battery, the potential of the positive electrode, and the potential of the negative electrode at the time of positive electrode deterioration of the battery, FIG. 4 which illustrates a relationship between the voltage of the battery, the potential of the positive electrode, and the potential of the negative electrode at the time of negative electrode deterioration of the battery, FIG. 5 which illustrates a relationship between the voltage of the battery, the potential of the positive electrode, and the potential of the negative electrode at the time of Li ion consumption deterioration of the battery, FIG. 6 which shows capacity derivative curves of the voltage of the battery, the potential of the positive electrode, and the potential of the negative electrode, FIG. 7 which is a configuration diagram of a multiple data integration unit, FIG. 8 which is a processing flowchart of the multiple data integration unit, FIG. 9 which illustrates peak positions appearing in voltage capacity derivative curves, FIG. 10 which illustrates change of a positive electrode peak position and a negative electrode peak position appearing in the voltage capacity derivative curves, and FIG. 11 and FIG. 12 which illustrate an example of deterioration degree diagnosis based on dV/dQ curves of the negative electrode and the positive electrode.

The entire configuration of a deterioration degree diagnosis device 100 of Embodiment 1 will be described with reference to FIG. 1.

An entire deterioration degree diagnosis device system includes the deterioration degree diagnosis device 100 and a battery 20 to be diagnosed. The battery 20 is not a part of the deterioration degree diagnosis device 100, but is closely related thereto, and thus a description will be given without distinguishing the battery 20.

The deterioration degree diagnosis device 100 includes a charging/discharging control unit 11 which has a function of charging the battery 20, a battery information measurement unit 12 which measures the current and the voltage of the battery 20, a multiple data integration unit 13 which integrates battery capacity voltage data obtained by the battery information measurement unit 12, and a deterioration degree diagnosis unit 14 which estimates a deterioration factor and a deterioration degree of the battery 20.

In the description, the battery capacity voltage data is battery capacity-voltage data, that is, data of voltage with respect to battery capacity.

A description will be given on the assumption that the battery 20 is a lithium ion battery. However, the type of the battery 20 is not limited to a lithium ion battery, and may be a lead storage battery, a nickel hydrogen battery, or the like.

Furthermore, the shape of the battery is not limited to a cylindrical shape shown in FIG. 1, and the technology described in Embodiment 1 is applicable to batteries having various shapes such as a stacked-type, a wound-type, and a button-type.

The battery 20 is not limited to a single battery, but may be a plurality of modules and packs connected in series or in parallel.

An on-vehicle charger used for an electric vehicle (EV) and a plug-in hybrid electrical vehicle (PHEV) and a charger and a power converter used for charging a mobile device and the like are assumed as the charging/discharging control unit 11. The charging/discharging control unit 11 may be a converter which is connected to a load, which is not shown, to perform discharging from the battery 20 to the load and has a bidirectional power conversion function.

The battery information measurement unit 12 has a function of measuring the current and the voltage of the battery 20 when the battery 20 is charged by the charging/discharging control unit 11, and measuring a capacity obtained by accumulating current values, and voltage transition.

The capacity measured by the battery information measurement unit 12 is a capacity Ah or Wh calculated by accumulating the current during charging over time.

Moreover, the capacity may be indicated by a capacity retention rate and a normalized state of charge SOC when a reference capacity and a capacity at the time of non-deterioration of the battery 20 are regarded as 100%.

Moreover, the battery information measurement unit 12 may measure the temperature of the battery 20.

The multiple data integration unit 13 integrates various battery capacity voltage data measured by the battery information measurement unit 12 when the battery 20 is charged by the charging/discharging control unit 11, and creates a battery capacity voltage curve. In the description, the battery capacity voltage curve is a battery capacity-voltage curve, that is, a curve of voltage with respect to battery capacity.

For example, when a charging operation in an electric vehicle is performed arbitrarily by the user, there is no guarantee that battery capacity voltage data in a charging range of 0% to 100% is obtained. Therefore, for data in different sections such as charging ranges of SOC 0 to 20%, 20 to 40%, 40 to 60%, 60 to 80%, and 80 to 100%, it is necessary to integrate battery capacity voltage data and create a battery capacity voltage curve.

Here, a deterioration phenomenon of a lithium ion battery will be described.

Deterioration of a secondary battery such as a lithium ion battery is a complex phenomenon of multiple deterioration modes. As deterioration of the battery 20, a phenomenon such as a decrease in output and a decrease in capacity occurs.

Furthermore, the phenomenon of a decrease in output and a decrease in capacity is caused by a combination of an increase in internal resistance, a decrease in positive electrode capacity, a decrease in negative electrode capacity, and Li ion consumption (Li ion consumption based on film growth that occurs on the surface of the negative electrode, and deposition on the electrode surface) as deterioration factors inside the battery.

As a method for identifying these deterioration factors, a method of analyzing the transition of the capacity and voltage during charging or discharging of the battery 20 is adopted.

Next, the method for analyzing the deterioration factors of the lithium ion battery will be described with reference to FIG. 2 to FIG. 6.

FIG. 2 is a diagram of a correlation between the voltage (open circuit voltage OCV) of the battery 20, the potential of positive electrode Li(Ni—Mn—Co)O2 which is commonly used in the battery 20, and the potential of negative electrode graphite.

In FIG. 2, the horizontal axis indicates the capacity (Q) of the battery 20. The vertical axis on the left side indicates the voltage of the battery 20, and the vertical axis on the right side indicates the potential of the positive electrode and the negative electrode of the battery 20. The same applies to FIG. 3 to FIG. 5.

Moreover, in FIG. 2, a voltage curve of the battery 20 is represented by a solid line, a potential curve of the positive electrode is represented by a broken line, and a potential curve of the negative electrode is represented by an alternate long and short dash line. The same applies to FIG. 3 to FIG. 6 and FIG. 9.

A voltage U of the battery 20 has the relationship of equation (1) with respect to potential (Open Circuit Potential (OCP) Up of the positive electrode and potential (OCP) Un of the negative electrode.

U=Up−Un (1)

Next, the influence on an OCV curve of the battery 20 is classified for each deterioration factor on the basis of the OCV curve of the battery 20 and OCP curves of the positive electrode and the negative electrode.

In FIG. 3, the OCV curve of the battery 20, the OCP curve of the positive electrode, and the OCP curve of the negative electrode when positive electrode deterioration occurs are shown with an OCV curve of an undeteriorated battery that is a new product which has not deteriorated.

When a battery voltage model at the time of a new product is defined by equation (1), a parameter ep caused by the positive electrode deterioration can be obtained by expressing a voltage model of a deteriorated battery by equation (2). Here, s is the capacity of the battery 20.

When the positive electrode deterioration occurs, the positive electrode OCP curve shrinks to the left, and as a result, the battery OCV curve has a higher voltage in the region where the SOC is higher than the middle.

Since the negative electrode OCP curve is almost flat, the position of the fully charged state (SOC=100%) of the battery 20 is almost determined by the positive electrode OCP curve. Therefore, the positive electrode deterioration has a great influence on the capacity of the battery 20, that is, the deterioration degree of the battery 20.

U(s)=Up(θp·s)−Un(s) (2)

FIG. 4 shows an OCV curve of the deteriorated battery, a positive electrode OCP curve, and a negative electrode OCP curve when negative electrode deterioration occurs, with the OCV curve of the undeteriorated battery that is a new product which has not deteriorated.

When only the negative electrode deterioration occurs, the negative electrode OCP curve shrinks to the left and the phase change position shifts, and as a result, the shape of the OCV curve of the battery 20 also changes. However, the influence thereof is limited. Unlike the case where only the positive electrode deterioration occurs, there is almost no influence on the shape of the battery OCV curve in the region where the SOC is higher than the middle.

This is because the shape of the OCP curve of negative electrode graphite is very flat. A parameter en caused by the negative electrode deterioration can be obtained by expressing a voltage model of a deteriorated battery by equation (3).

U(s)=Up(s)−Un(θn·s) (3)

FIG. 5 shows an OCV curve of the deteriorated battery, a positive electrode OCP curve, and a negative electrode OCP curve when SOC shift between the positive and negative electrodes occurs due to lithium consumption, with the OCV curve of the new battery which has not deteriorated.

When the SOC shift between the positive and negative electrodes occurs due to lithium ion consumption, the positive electrode OCP curve shifts to the left in the entire SOC region, and the battery OCV curve has a higher voltage as a whole.

The difference from the case where only the positive electrode deterioration occurs is that the battery OCV curve becomes higher even in the region where the SOC is lower than the middle. A deterioration parameter et caused by lithium ion consumption can be obtained by expressing a voltage model of a battery deteriorated by lithium consumption, by equation (4).

U(s)=Up(s+θt)−Un(s) (4)

The change of the OCV curve of the battery 20 and the OCP curves of the positive electrode and the negative electrode due to each deterioration factor has been described above. However, since the transition of the battery voltage with respect to the capacity has small change, it is difficult to identify each deterioration factor on the basis of the change of the OCV curve of the battery 20.

Therefore, the deterioration factor can be identified by analyzing the change of the positive electrode OCP curve and the negative electrode OCP curve on the basis of a dV/dQ curve which is a derivative curve obtained by differentiating the OCV curve of the battery 20 by capacity.

Next, a method for identifying the deterioration factor by analyzing the derivative curve of the battery capacity voltage curve of the battery 20, that is, a dV/dQ curve thereof, will be described.

FIG. 6 shows dV/dQ curves obtained by differentiating the OCV curve of the battery 20 in which, as an example, Li(Ni—Mn—Co)O2 is used for the positive electrode and graphite is used for the negative electrode, the positive electrode OCP curve, and the negative electrode OCP curve by capacity.

In FIG. 6, the horizontal axis indicates the capacity (Q) of the battery, and the vertical axis indicates dV/dQ.

In the dV/dQ curve of negative electrode graphite which is commonly used, a peak due to a phase change appears depending on the state of charge. In addition, in the dV/dQ curve of positive electrode Li(Ni—Mn—Co)O2, a peak due to a phase change appears depending on the state of charge.

The dV/dQ curve of the positive electrode has a shape in which a peak appears as the SOC increases from the middle SOC. The dV/dQ curve of the negative electrode shows a shape having several peaks.

A parameter related to each deterioration factor can be estimated by approximating the dV/dQ curve of the positive electrode and the dV/dQ curve of the negative electrode with peak functions. For example, the peak function for the positive electrode can be expressed by addition of a constant term and a sigmoid function. The peak function for the negative electrode can generally be expressed by the cumulative function of a Cauchy distribution and the sum of logistic functions.

As an example, a logistic distribution function is shown in equation (5).

Here, x denotes the capacity of the battery 20, p denotes a median value, d denotes a variance value, and k denotes a peak height.

f(x)=k/(1+exp(−(x−μ)/d) (5)

Here, the function of the multiple data integration unit 13 will be described with reference to FIG. 7 and FIG. 8.

FIG. 7 is a configuration diagram of the multiple data integration unit 13.

The multiple data integration unit 13 includes a data storage unit 31 and a data integration unit 32. The multiple data integration unit 13 stores various battery capacity voltage data obtained by the battery information measurement unit 12, in the data storage unit 31, and integrates these multiple battery capacity voltage data by the data integration unit 32.

As the processing of the multiple data integration unit 13, various capacity-voltage data obtained by the battery information measurement unit 12 may be analyzed as a derivative voltage curve, and whether or not to store or whether or not to integrate the capacity-voltage data may be determined.

The processing flow by the multiple data integration unit 13 will be described with reference to FIG. 8.

In step 1 (S01), battery capacity voltage data measured by the battery information measurement unit 12 is acquired from the data storage unit 31.

In step 2 (S02), the battery capacity voltage data (curve) is differentiated by the capacity (Q), and dV/dQ curve analysis is performed.

In step 3 (S03), peaks based on the positive electrode and the negative electrode in the battery 20 are detected.

In step 4 (S04), it is determined whether sufficient data for performing deterioration diagnosis of the battery 20 by the deterioration degree diagnosis unit 14 has been acquired. Specifically, it is determined whether or not peaks A and B related to the negative electrode and a peak C related to the positive electrode which will be described with reference to FIG. 9 and FIG. 10 have been detected.

In step 5 (S05), since it is determined in step 4 (S04) that the amount of the data is insufficient, battery capacity voltage data is further acquired from the data storage unit 31.

In step 6 (S06), the newly acquired battery capacity voltage data is integrated with the already acquired battery capacity voltage data. Then, after integrating the battery capacity voltage data, the processing returns to step 2 (S02).

In step 7 (S07), since it is determined in step 4 (S04) that the amount of the data is sufficient, the battery capacity voltage data (curve) is transmitted to the deterioration degree diagnosis unit 14.

Next, the function of the deterioration degree diagnosis unit 14 will be described with reference to FIG. 9 and FIG. 10.

In FIG. 9, FIG. 10A, and FIG. 10B, the horizontal axis indicates the capacity (Q) of the battery, and the vertical axis indicates dV/dQ. In FIG. 9, D is a “data range where negative electrode peaks A and B and positive electrode peaks C of an undeteriorated battery and a deteriorated battery can be detected”, as will be described later.

In FIG. 10A, a dV/dQ curve related to the negative electrode is represented by a solid line for non-deterioration, represented by a broken line for negative electrode deterioration, and represented by an alternate long and short dash line for negative electrode shift due to Li consumption.

In FIG. 10B, a dV/dQ curve related to the positive electrode is represented by a solid line for non-deterioration, represented by a broken line for negative electrode deterioration, and represented by an alternate long and short dash line for negative electrode shift due to Li consumption.

The deterioration degree diagnosis unit 14 analyzes a dV/dQ curve obtained by differentiating the battery capacity voltage curve created by the multiple data integration unit 13, and estimates deterioration parameters related to positive electrode deterioration, negative electrode deterioration, and Li ion consumption.

When estimating the deterioration parameters, a normalized capacity calculated on the basis of the capacity of the undeteriorated battery or the capacity of a battery serving as a reference, or the state of charge SOC is used for the capacity of the dV/dQ curve, whereby the deterioration parameters of the deteriorated battery 20 can be estimated from the undeteriorated battery.

For example, the deterioration parameter en caused by the negative electrode can be estimated by detecting the peak A and the peak B appearing in the dV/dQ curve of the negative electrode in FIG. 9, and observing the distances between the peaks A and the peaks B of the deteriorated battery 20 and the undeteriorated battery.

FIG. 10A illustrates an example of change of the peak function appearing in the dV/dQ curve of the negative electrode. The peak function appearing in the dV/dQ curve of the negative electrode of the undeteriorated battery shrinks as a whole when negative electrode deterioration occurs, so that the distance between the peak A and the peak B is shortened.

In FIG. 9, it is possible to detect the peaks C appearing in the dV/dQ curves of the positive electrodes of the undeteriorated battery and the deteriorated battery, and when the height of each peak C is observed, the deterioration parameter ep caused by the positive electrode can be estimated

FIG. 10B illustrates an example of change of the peak C appearing in the dV/dQ curve of the positive electrode. When positive electrode deterioration occurs, the height of the peak C is larger than that of the peak C of the undeteriorated battery.

In addition, the deterioration parameter θt caused by Li consumption can be identified by observing the shift amounts of the peak A and the peak B from the negative electrode dV/dQ curves of the undeteriorated battery and the deteriorated battery and observing the shift amount of the peak C from the positive electrode dV/dQ curves of the undeteriorated battery and the deteriorated battery.

When deterioration based on Li consumption occurs, shifts of the negative electrode peak in FIG. 10A and the positive electrode peak C in FIG. 10B occur. If the positive electrode peak C is in the data range where the peak A and the peak B of the negative electrode are observed, each deterioration parameter can be estimated from the height of the peak C and the shift of the peak C position.

In FIG. 10A and FIG. 10B, the line on the left side of the vertical axis is a part that is not actually observed. The negative electrode shift and the positive electrode shift due to the respective deterioration factors are shown such that the entireties thereof are easy to understand.

The deterioration degree diagnosis unit 14 can estimate a battery capacity voltage curve from the usage upper limit voltage to the lower limit voltage specified by the battery 20 itself or a device, by observing the battery capacity voltage data and the capacity-dV/dQ curve corresponding to the data range D (see FIG. 9) where the negative electrode peaks A and B and the positive electrode peaks C of the undeteriorated battery and the deteriorated battery can be detected. The deterioration degree diagnosis unit 14 can estimate the capacity of the deteriorated battery with respect to the capacity of the undeteriorated battery or the battery serving as a reference, that is, the deterioration degree of the deteriorated battery.

With such a configuration, it is possible to estimate a battery capacity voltage curve corresponding to the battery usage range from the minimum required battery capacity voltage data, and accurately diagnose the deterioration degree, so that voltage data during charging or discharging in the entire battery usage range is not required.

Next, an example of the result of deterioration degree diagnosis based on the peaks A and B of the dV/dQ curve of the negative electrode and the peak C of the dV/dQ curve of the positive electrode will be described with reference to FIG. 11 and FIG. 12.

FIG. 11 shows a voltage curve and partial charging data of the deteriorated battery (capacity retention rate: 84%).

In FIG. 11, the horizontal axis indicates the capacity (%) of the battery, and the vertical axis indicates the voltage of the battery 20.

In FIG. 11, actual measured partial charging data is represented by a thick solid line, and an estimated battery capacity voltage curve is represented by a thick broken line. In FIG. 11, the estimated battery capacity voltage curve is described as an estimated voltage curve.

FIG. 12 shows a derivative dV/dQ curve of the voltage curve in FIG. 11.

In FIG. 12, the horizontal axis indicates the capacity (%) of the battery, and the vertical axis indicates dV/dQ.

In FIG. 12, a derivative curve of the actual measured partial charging data is represented by a thick solid line, and a derivative curve of the estimated battery capacity voltage curve is represented by a thick broken line. A positive electrode dV/dQ curve is represented by a thin broken line, and a negative electrode dV/dQ curve is represented by a thin alternate long and short dash line. In FIG. 12, the estimated battery capacity voltage curve is described as an estimated voltage curve.

The negative electrode peaks A and B and the positive electrode peak C are detected from the partial charging data, and comparison with the undeteriorated battery is performed as described with reference to FIG. 10, whereby the negative electrode deterioration parameter en due to the change in the distance between the peak A and the peak B of the negative electrode and a deterioration parameter θt by Li consumption due to the shift amounts of the peak A and the peak B of the negative electrode can be estimated. In addition, the positive electrode deterioration parameter Op due to the change in the position (height) of the positive electrode peak C and the deterioration parameter θt caused by Li consumption due to a shift of the positive electrode peak C can be estimated.

As a result of estimating the battery capacity voltage curve in the entire usage range of the battery 20 as shown in FIG. 11 and FIG. 12, the capacity position corresponding to the point of intersection of the estimated battery capacity voltage curve and the upper limit voltage shows a deterioration degree of 84% in FIG. 11.

The multiple data integration unit 13 may create battery capacity voltage data that allow at least the negative electrode peaks A and B and the positive electrode peak C to be observed, on the basis of various battery capacity voltage data. Alternatively, the multiple data integration unit 13 can create battery capacity voltage data so as to include the data range D in FIG. 9.

With such a configuration, by including the multiple data integration unit 13, it is possible to create the data required to estimate the entire battery capacity voltage curve from randomly collected data. Therefore, it is possible to accurately estimate the deterioration degree of the battery 20 even in a device in which the battery 20 is charged or discharged through a user-arbitrary operation.

Moreover, as shown in FIG. 10A, when the dV/dQ curve of the negative electrode shrinks due to the negative electrode deterioration, the position of the peak due to the increase in dV/dQ observed near the lower limit capacity does not change, and the distance between the peak A and the peak B of the negative electrode shortened in some cases. In such a case, the lower limit voltage of the battery does not change due to the negative electrode deterioration, and the upper limit voltage of the battery is influenced only by the positive electrode deterioration as described above, so that the change of the entire voltage curve and the deterioration degree (capacity) of the battery are not influenced by the negative electrode deterioration.

Therefore, for the deteriorated battery, the entire voltage curve of the battery can be estimated by detecting only the positive electrode peak C, and the deterioration degree of the battery can be diagnosed.

In addition, in the dV/dQ curve of the negative electrode, peaks other than the peaks A and B appear, so that the parameter due to the negative electrode deterioration can be estimated by analyzing the other peaks. However, since the peak C of the positive electrode appears in the range where the peaks A and B appear in the dV/dQ curve of the negative electrode, even if a peak other than the peaks A and B in the dV/dQ curve of the negative electrode is detected, it may be impossible to identify the deterioration factor for the positive electrode.

However, if the deterioration degree of the positive electrode is a state known in advance, the negative electrode deterioration parameter may be estimated on the basis of the peak other than the peaks A and B in the dV/dQ curve of the negative electrode, a battery capacity voltage curve in the battery usage range may be estimated, and the deterioration degree may be diagnosed on the basis of the battery capacity voltage curve.

In the above description, the peaks appearing in the dV/dQ curve of the battery in which Li(Ni—Mn—Co)O2 is used for the positive electrode and graphite is used for the negative electrode have been described as an example. However, for example, LiCoO2 or LiFePO4 may be used for the positive electrode, and a material such as lithium titanate may be used for the negative electrode. If the materials of the positive electrode and the negative electrode are different, the positions of the appearing peaks may be different.

In such a case, the multiple data integration unit 13 may define a data range used when the battery capacity voltage curve of the entire battery 20 is estimated at the time of initial voltage curve analysis, and may create battery capacity voltage data so as to satisfy the defined data range, from various multiple battery capacity voltage data.

With such a configuration, even without initially defining a data range required to estimate the voltage curve of the entire battery 20, it is possible to calculate a data range required to estimate the entire battery capacity voltage curve from various multiple battery capacity voltage data, and accurately diagnose the deterioration degree of the battery.

Furthermore, the multiple data integration unit 13 may calculate a derivative voltage curve for various battery capacity voltage data to perform data integration.

The voltage of the battery 20 has the relationship of equation (6) with respect to a battery OCV and the product of internal resistance R and the value of a flowing current. Since the product IR of the resistance R and a current I in equation (6) is a constant term, the influence of IR can be eliminated by differentiating the voltage with respect to the capacity when analyzing the voltage curve, and the OCV curve of the battery 20 can be analyzed.

V=OCV+IR (6)

The deterioration degree diagnosis unit 14 diagnoses the deterioration degree of the battery by analyzing the dV/dQ curve obtained by differentiating the battery capacity voltage curve created by the multiple data integration unit 13, by capacity, identifying the deterioration factor of the battery, and estimating the battery capacity voltage curve corresponding to the battery usage range.

However, peaks in a first-order derivative curve may be complicated and difficult to analyze, or it may be impossible to distinguish and analyze the peaks of the positive electrode and the negative electrode since these peaks overlap. In such a case, second-order differentiation by capacity may be further performed, and a second-order derivative voltage curve may be analyzed. The number of times of differentiation may be further increased in order to facilitate peak analysis.

With such a configuration, even if peaks are complicated and cannot be analyzed when analyzing the dV/dQ curve obtained by differentiating the battery capacity voltage curve by capacity, since only a part having a larger peak change is extracted by performing second-order differentiation, and the other peaks are averaged, it may be easier to perform the analysis. Therefore, it is possible to identify the deterioration factor, estimate the voltage curve in the battery usage range, and accurately diagnose the deterioration degree of the battery.

As described above, the deterioration degree diagnosis device of Embodiment 1 includes a charging/discharging control unit configured to control charging or discharging of a battery; a battery information measurement unit configured to measure a voltage and a current of the battery and measure a capacity and voltage transition during charging or discharging; a multiple data integration unit configured to integrate battery capacity voltage data in at least two different sections measured by the battery information measurement unit, and create a battery capacity voltage curve; and a deterioration degree diagnosis unit configured to estimate a deterioration degree of the battery on the basis of the battery capacity voltage curve, and the deterioration degree diagnosis unit analyzes a derivative curve of the battery capacity voltage curve, identifies deterioration factors based on a positive electrode, a negative electrode, and Li ion consumption, and estimates the deterioration degree of the battery.

Therefore, even when a charging operation as in an electric vehicle is a user-arbitrary operation, the deterioration degree diagnosis device of Embodiment 1 can accurately estimate the deterioration degree of the battery.

### Embodiment 2

A deterioration degree diagnosis device of Embodiment 2 is obtained by adding a temperature data conversion unit to the multiple data integration unit of the deterioration degree diagnosis device of Embodiment 1.

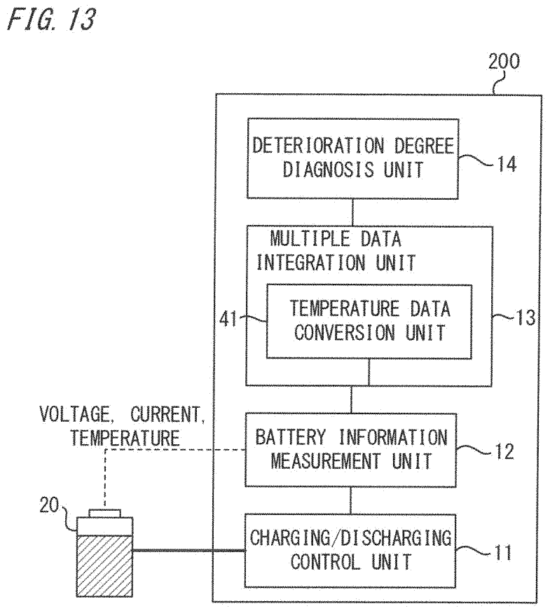

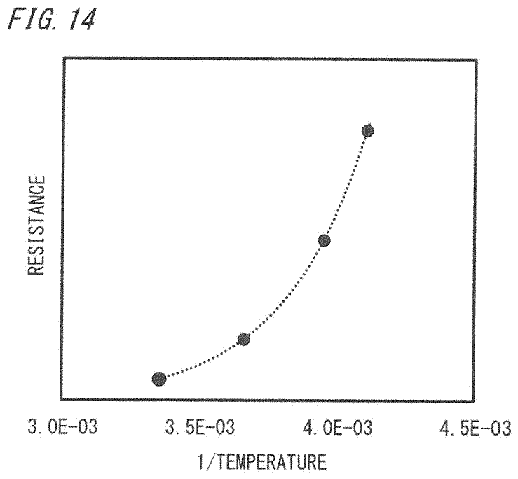

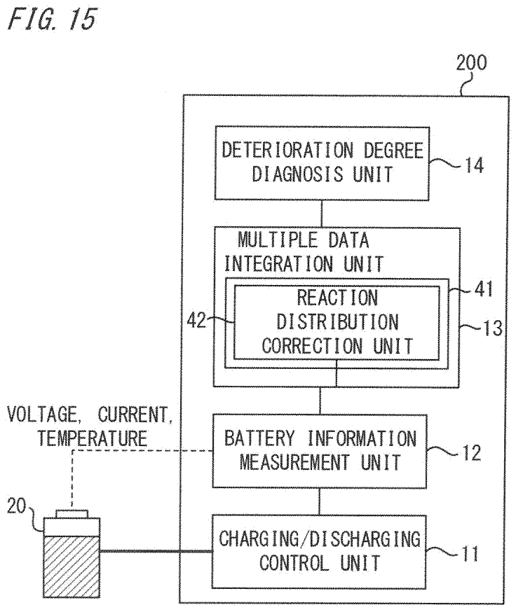

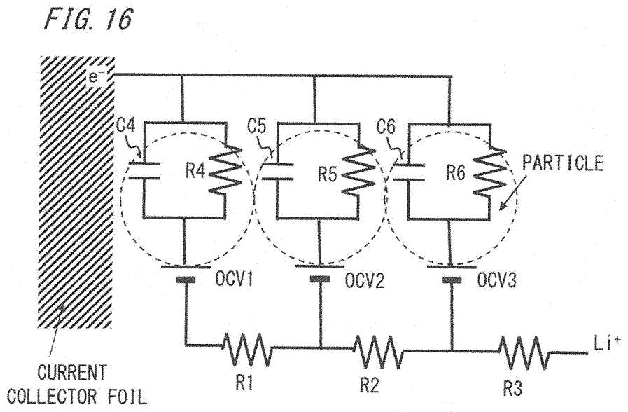

The deterioration degree diagnosis device of Embodiment 2 will be described, focusing on the differences from Embodiment 1, with reference to FIG. 13 which is a configuration diagram of the deterioration degree diagnosis device, FIG. 14 which illustrates a correlation between the internal resistance and the temperature of a battery, FIG. 15 which is a configuration diagram of an application example of the deterioration degree diagnosis device, and FIG. 16 which illustrates a reaction distribution model of an electrode.

In the configuration diagram of Embodiment 2, parts that are the same as or correspond to those in Embodiment 1 are denoted by the same reference characters.

The entire configuration of a deterioration degree diagnosis device 200 of Embodiment 2 will be described with reference to FIG. 13.

The deterioration degree diagnosis device 200 includes a charging/discharging control unit 11 which has a function of charging a battery 20, a battery information measurement unit 12 which measures the current, the voltage, and the temperature of the battery 20, a multiple data integration unit 13 which integrates battery capacity voltage data obtained by the battery information measurement unit 12, and a deterioration degree diagnosis unit 14 which estimates a deterioration parameter and a deterioration degree of the battery 20. The multiple data integration unit 13 includes a temperature data conversion unit 41 which corrects the data obtained by the battery information measurement unit 12, to a predetermined temperature condition.

First, a correlation between the internal resistance and the temperature of the battery 20 will be described with reference to FIG. 14.

In FIG. 14, the horizontal axis indicates the reciprocal (1/T) of a temperature T of the battery 20, and the vertical axis indicates the internal resistance R of the battery 20.

A lithium ion battery has the characteristic that the internal resistance changes depending on the environmental temperature, the resistance increases as the temperature decreases, and the resistance decreases as the temperature increases.

FIG. 14 shows an example of the correlation between the internal resistance and the temperature of the battery 20 which is a lithium ion battery. For example, at a low temperature, the resistance value becomes large, so that an overvoltage IR becomes large. At a low temperature, even if the battery is charged with the same current value and the same power as those at a high temperature, when battery capacity voltage data at the low temperature and battery capacity voltage data at the high temperature are integrated, the difference due to an overvoltage is large, so that it is difficult to obtain a battery capacity voltage curve satisfying a predetermined condition.

Therefore, the temperature data conversion unit 41 may be configured to integrate multiple battery capacity voltage data of the battery 20 having different temperatures after, for example, the voltage of the battery 20 is corrected to a predetermined temperature condition on the basis of the correlation map between the resistance and the temperature in FIG. 14 and a mathematical expression, that is, the difference due to temperature is corrected.

With such a configuration, even when observation data at various temperatures are obtained, it is possible to create a battery capacity voltage curve corresponding to a predetermined data range, and an accurate deterioration degree of the battery 20 can be estimated.

Next, handling a reaction distribution generated in the lithium ion battery will be described with reference to FIG. 15 and FIG. 16.

FIG. 15 is a configuration diagram in which a reaction distribution correction unit 42 is provided in the temperature data conversion unit 41 of the deterioration degree diagnosis device 200.

In the lithium ion battery, a phenomenon that a reaction distribution in the electrode thickness direction or plane direction in the battery 20 occurs especially at a low temperature, is known.

FIG. 16 shows an example of a multi-particle circuit model for describing the reaction distribution.

In FIGS. 16, R1, R2, and R3 are electrolyte resistances (solution resistance, viscosity resistance of an electrolyte) that contribute to the transfer of Li ions in the electrolyte in the lithium ion battery 20.

R4, R5, and R6 represent diffusion resistances (reaction resistance, charge transfer resistance, resistance based on interparticle diffusion and intraparticle diffusion) of electrode particles and Li ions, and C4, C5, and C6 are capacitances based on an electric double layer capacity. In addition, OCV1, OCV2, and OCV3 are each a model battery open circuit voltage. A current collector foil is a main component that forms an electrode.

For example, since the difference between the electrolyte resistances R1, R2, and R3 becomes large at a low temperature, even if the respective circuit constants of a CR parallel circuit of R4 and C4, a CR parallel circuit of R5 and C5, and a CR parallel circuit of R6 and C6 are the same, the current flowing in each modeled battery is not uniform, and the difference therebetween becomes large.

Even when a battery capacity voltage curve measured in this state is differentiated by capacity, since there is a difference in the current flowing through each resistance, the influence of the constant term cannot be eliminated. In addition, the open circuit voltage (OCV) of the observed battery 20 is not an accurate value.

In this state, when the multiple data integration unit 13 integrates the data measured in normal-temperature, high-temperature, and low-temperature environments, an accurate battery capacity voltage curve cannot be created, so that an error may occur in deterioration degree diagnosis.

For the obtained charge voltage data, the reaction distribution correction unit 42 estimates the electrolyte resistances R1, R2, and R3 on the basis of the circuit model shown in FIG. 16, and then estimates OCV1, OCV2, and OCV3 of the model batteries. At that time, it is assumed that the constants (R4, C4, R5, C5, R6, C6) of the CR parallel circuits show the same value. The open circuit voltage (OCV) of the battery 20 to be analyzed in deterioration degree diagnosis is the average voltage of OCV1, OCV2, and OCV3 of the model batteries. By calculating the open circuit voltage (OCV) of the battery 20 on the basis of this average voltage and then integrating the data at a low temperature, normal temperature, and a high temperature, the reaction distribution inside the battery electrode can be corrected.

In this circuit model, as an example, the reaction resistance and diffusion resistance are unified as a parallel circuit of R and C, but the number of CR parallel circuits arranged in series may be divided for each resistance component. Moreover, the number of particles may be further increased to increase the number of CR parallel circuits arranged in parallel.

Furthermore, calculation may be performed for the actual measured data of the battery capacity voltage such that an error is the smallest, and the number of installed circuits may be determined.

With such a configuration, even when data including the influence of the reaction distribution is obtained at the battery 20 especially at a low temperature, the battery capacity voltage data, obtained at a low temperature and corrected for the reaction distribution, is integrated with the battery capacity voltage data at normal temperature and a high temperature, and a battery capacity voltage curve can be created. Then, an accurate deterioration degree of the battery 20 can be estimated by analyzing the battery capacity voltage curve and performing deterioration degree diagnosis.

The reaction distribution in the electrode of the battery 20 is a phenomenon that occurs even when the value of a current flowing through the battery 20 is large.

Therefore, the reaction distribution correction unit 42 may be configured to correct the voltage of the battery 20 on the basis of the circuit model in FIG. 16 and the mathematical model, based on the current value when charging the battery 20 by the charging/discharging control unit 11.

With such a configuration, even when a charging or discharging operation is performed at a large current (about 0.2 C or more) for the battery 20, after correction is performed by the reaction distribution correction unit 42, the multiple data integration unit 13 can integrate the battery capacity voltage data, and an accurate deterioration degree of the battery 20 can be diagnosed.

As described above, the deterioration degree diagnosis device of Embodiment 2 is obtained by adding the temperature data conversion unit to the multiple data integration unit of the deterioration degree diagnosis device of Embodiment 1.

Therefore, even when a charging operation as in an electric vehicle is a user-arbitrary operation, the deterioration degree diagnosis device of Embodiment 2 can accurately estimate the deterioration degree of the battery, and can further eliminate the influence of the temperature of the battery and accurately estimate the deterioration degree of the battery.

### Embodiment 3

A deterioration degree diagnosis device of Embodiment 3 is obtained by adding a hysteresis correction unit to the multiple data integration unit of the deterioration degree diagnosis device of Embodiment 1.

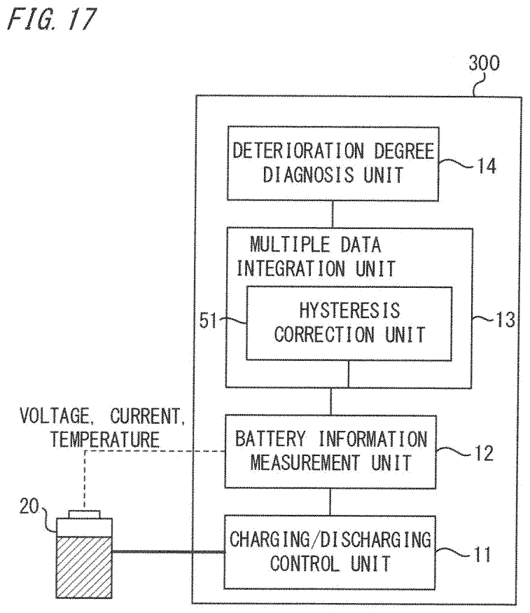

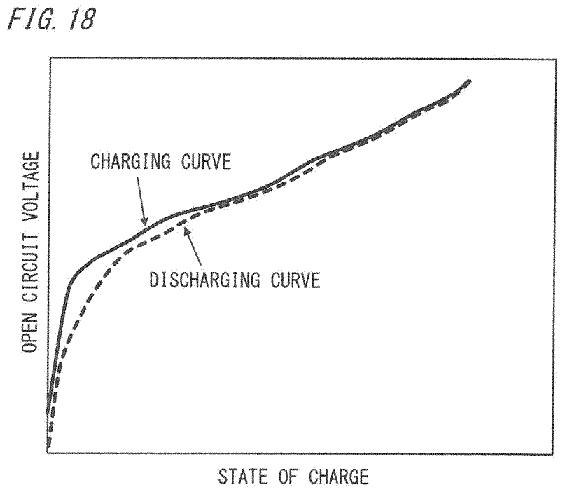

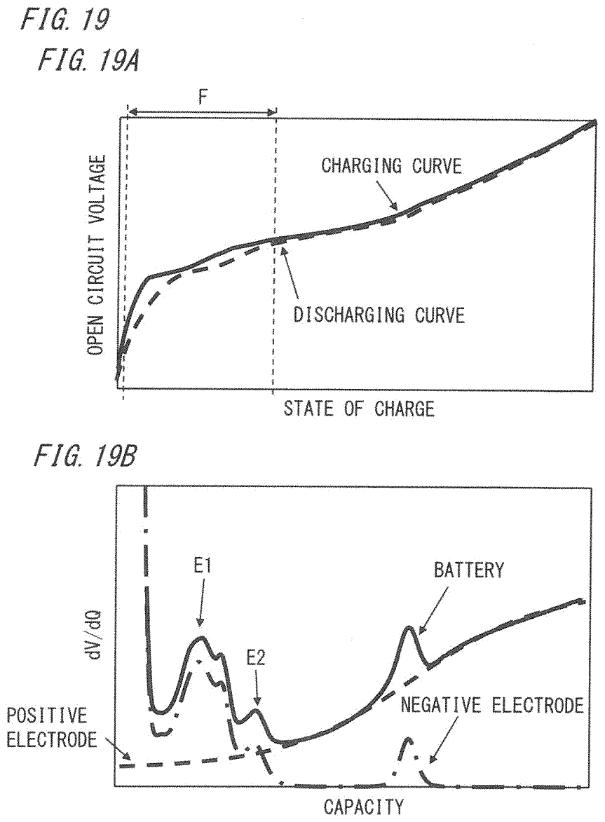

The deterioration degree diagnosis device of Embodiment 3 will be described, focusing on the differences from Embodiment 1, with reference to FIG. 17 which is a configuration diagram of the deterioration degree diagnosis device, FIG. 18 which illustrates a hysteresis phenomenon of a battery, and FIG. 19A and FIG. 19B which illustrate peak positions appearing in voltage capacity derivative curves when a hysteresis occurs.

In the configuration diagram of Embodiment 3, parts that are the same as or correspond to those in Embodiment 1 are denoted by the same reference characters.

The entire configuration of a deterioration degree diagnosis device 300 of Embodiment 3 will be described with reference to FIG. 17.

The deterioration degree diagnosis device 300 includes a charging/discharging control unit 11 which has a function of charging a battery 20, a battery information measurement unit 12 which measures the current, the voltage, and the temperature of the battery 20, a multiple data integration unit 13 which integrates battery capacity voltage data obtained by the battery information measurement unit 12, and a deterioration degree diagnosis unit 14 which estimates a deterioration parameter and a deterioration degree of the battery 20. The multiple data integration unit 13 includes a hysteresis correction unit 51 which corrects a hysteresis during charging or discharging of the battery 20.

A hysteresis phenomenon in which a difference occurs between the state of charge SOC-OCV characteristics during charging and during discharging, occurs in the lithium ion battery 20.

FIG. 18 shows a hysteresis of the SOC-OCV characteristics during charging and during discharging.

In FIG. 18, the horizontal axis indicates the state of charge (SOC) of the battery 20, and the vertical axis indicates the open circuit voltage (OCV) of the battery 20. In addition, in FIG. 18, a charging curve of the hysteresis is represented by a solid line, and a discharging curve of the hysteresis is represented by a broken line.

For example, when the battery 20 is discharged to the lower limit SOC and then charged by the charging/discharging control unit 11, the open circuit voltage (OCV) of the battery 20 changes according to the charging SOC-OCV curve. However, when the battery 20 is charged from a state of charge (SOC) in an intermediate range, a phenomenon is generally known in which the open circuit voltage (OCV) of the battery 20 changes according to the discharging SOC-OCV curve.

When the multiple data integration unit 13 integrates battery capacity voltage data of the battery 20 in which a hysteresis has occurred, a battery capacity voltage curve to be analyzed cannot be accurately created, so that it may be impossible to accurately perform deterioration degree diagnosis. However, by correcting the open circuit voltage (OCV) of the battery 20 by the hysteresis correction unit 51 and then performing integration, it is possible to accurately diagnose the deterioration degree.

Moreover, correcting the hysteresis of the open circuit voltage (OCV) of the battery 20 by the hysteresis correction unit 51 is effective even for the case of correcting the change in battery voltage due to the difference in internal resistance and the reaction distribution inside the battery which are caused by the temperature as described in Embodiment 2.

Therefore, by adding the hysteresis correction unit 51 of Embodiment 3 to the configuration of the deterioration degree diagnosis device of Embodiment 2 and correcting the difference due to the hysteresis of the battery 20, it is possible to more accurately diagnose the deterioration degree of the battery 20.

FIG. 19A and FIG. 19B show an example of an SOC-OCV curve and a dV/dQ curve showing a range where a hysteresis phenomenon occurs.

In FIG. 19A, F is a “range where the difference between a charging curve and a discharging curve of the hysteresis is large”, as will be described later.

In FIG. 19A, the horizontal axis indicates the state of charge (SOC) of the battery 20, and the vertical axis indicates the open circuit voltage (OCV) of the battery 20. In addition, in FIG. 19A, the charging curve of the hysteresis is represented by a solid line, and the discharging curve of the hysteresis is represented by a broken line.

In FIG. 19B, the horizontal axis indicates the capacity of the battery 20, and the vertical axis indicates dV/dQ. In addition, in FIG. 19B, dV/dQ of the battery voltage is represented by a solid line, dV/dQ of the positive electrode potential is represented by a broken line, and dV/dQ of the negative electrode potential is represented by an alternate long and short dash line.

As can be seen from FIG. 19A and FIG. 19B, the hysteresis phenomenon is a phenomenon that occurs when charging is started from the position of the range F where the difference between the charging SOC-OCV curve and the discharging SOC-OCV curve is large, or the position at which a peak E1 or E2 of the negative electrode appears in the dV/dQ curve.

Therefore, the hysteresis correction unit 51 may refer to a range corresponding to the region F of the SOC-OCV curve or the negative electrode peaks E1 and E2, and may select and integrate battery capacity voltage data obtained when charging is started from an SOC higher than these ranges, and battery capacity voltage data obtained when charging is started from an SOC exceeding the position of the negative electrode peak E1 or E2.

Furthermore, the position of the negative electrode peak of the dV/dQ curve which serves as a reference for selecting battery capacity voltage data may be set to the position at which the peak E1 or E2 is detected by observing multiple battery capacity voltage data. Moreover, the position at which a hysteresis phenomenon occurs during charging may be stored in advance for determination.

Furthermore, the hysteresis correction unit 51 may determine the operation history of the battery 20 before the start of charging by the charging/discharging control unit 11, and may make selection such that data of the same operation history are integrated and data having different operation histories are not integrated by the multiple data integration unit 13.

Also, when the rest time (no-load state time) of the battery before the start of charging by the charging/discharging control unit 11 is sufficiently long, a hysteresis is relaxed, so that the multiple data integration unit 13 may select battery capacity voltage data to be integrated, with the length of the rest time as a threshold value.

Moreover, the hysteresis correction unit 51 may have a model (hysteresis model) for correcting a hysteresis during charging and discharging of the battery 20, may calculate battery capacity voltage data after correcting the hysteresis, and the multiple data integration unit 13 may integrate these battery capacity voltage data and create a battery capacity voltage curve.

As for the hysteresis model representing the hysteresis phenomenon, for example, the open circuit voltage (OCV) positioned by the state of charge (SOC) (0 to 100%) at the start of charging or the state of charge (SOC) at the start of discharging in the charging OCV and discharging OCV curves with respect to the state of charge (SOC) of the battery 20 in FIG. 18 may be held as a map or expressed as a function.

It is also generally known that the hysteresis model changes depending on the temperature, so that a map and a function may be provided for each temperature.

With such a configuration, the hysteresis correction unit 51 further accurately corrects battery capacity voltage data, and then the multiple data integration unit 13 integrates the battery capacity voltage data and creates a battery capacity voltage curve, whereby it is possible to accurately diagnose the deterioration degree.

As described above, the deterioration degree diagnosis device of Embodiment 3 is obtained by adding the hysteresis correction unit to the multiple data integration unit of the deterioration degree diagnosis device of Embodiment 1.

Therefore, even when a charging operation as in an electric vehicle is a user-arbitrary operation, the deterioration degree diagnosis device of Embodiment 3 can accurately estimate the deterioration degree of the battery, and can further eliminate the influence of a hysteresis of charging and discharging and accurately estimate the deterioration degree of the battery.

### Embodiment 4

A deterioration degree diagnosis device of Embodiment 4 is obtained by adding a deterioration correction unit to the multiple data integration unit of the deterioration degree diagnosis device of Embodiment 1.

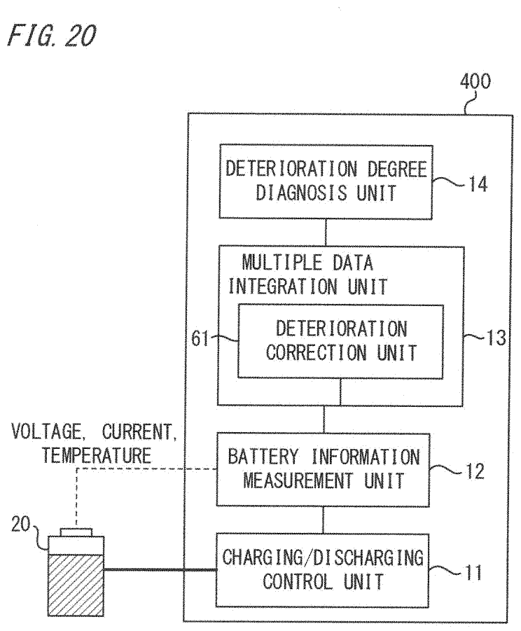

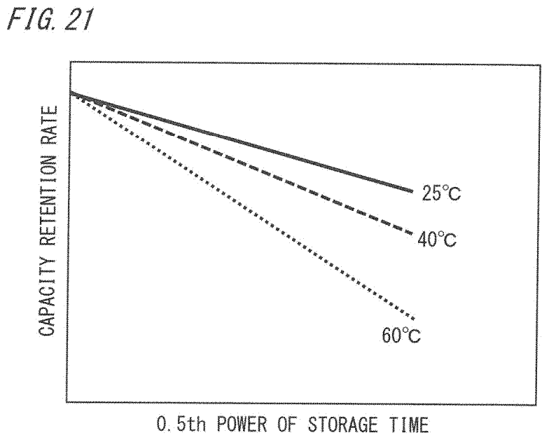

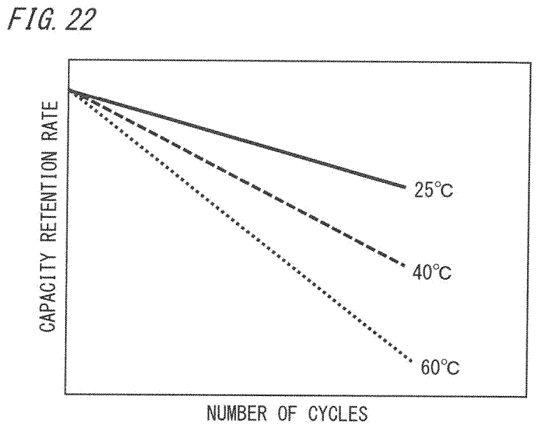

The deterioration degree diagnosis device of Embodiment 4 will be described, focusing on the differences from Embodiment 1, with reference to FIG. 20 which is a configuration diagram of the deterioration degree diagnosis device, FIG. 21 which illustrates a correlation between a storage deterioration pattern and the temperature of a battery, and FIG. 22 which illustrates a correlation between a cycle deterioration pattern and the temperature of the battery.

In the configuration diagram of Embodiment 4, parts that are the same as or correspond to those in Embodiment 1 are denoted by the same reference characters.

The entire configuration of a deterioration degree diagnosis device 400 of Embodiment 4 will be described with reference to FIG. 20.

The deterioration degree diagnosis device 400 includes a charging/discharging control unit 11 which has a function of charging a battery 20, a battery information measurement unit 12 which measures the current, the voltage, and the temperature of the battery 20, a multiple data integration unit 13 which integrates battery capacity voltage data obtained by the battery information measurement unit 12, and a deterioration degree diagnosis unit 14 which estimates a deterioration parameter and a deterioration degree of the battery 20. The multiple data integration unit 13 includes a deterioration correction unit 61 which corrects storage deterioration and cycle deterioration of the battery 20.

The difference in measurement time may be long between the battery capacity voltage data to be integrated by the multiple data integration unit 13. In this case, it is assumed that a deterioration degree differs due to the long-term use of the battery 20.

When the deterioration degrees of the data to be integrated are significantly different, the peak positions of the positive electrode and the negative electrode when analyzing the battery capacity voltage curve change between the battery capacity voltage data to be integrated. Thus, even when such battery capacity voltage data are integrated and deterioration degree diagnosis is performed, it is not possible to accurately diagnose the change from an undeteriorated battery, a reference battery, or the deterioration degree of the battery 20 estimated at the time of the previous deterioration degree diagnosis.

Therefore, the deterioration correction unit 61 in the multiple data integration unit 13 corrects the deterioration degrees of various battery capacity voltage data, that is, corrects the difference between the data. The multiple data integration unit 13 integrates the corrected multiple battery capacity voltage data and creates a battery capacity voltage curve.

With such a configuration, even when the difference in measurement time between the battery capacity voltage data is long and the deterioration degrees of the battery capacity voltage data to be integrated are different, it is possible to create a battery capacity voltage curve, and an accurate deterioration degree of the battery 20 can be estimated.

Specifically, in order to correct the deterioration degrees of multiple battery capacity voltage data, for example, the temperature, the number of storage days, the number of charging/discharging cycles of the battery 20, and a deterioration model representing transition of the charging/discharging SOC range and transition of the deterioration degree may be held in advance. Alternatively, after some deterioration degrees are estimated, a correlation between the usage history and the deterioration degree of the battery may be estimated.

It is noted that the deterioration degree estimated by the deterioration correction unit 61 on the basis of the deterioration model may be different from the deterioration degree actually estimated by the deterioration degree diagnosis unit 14, and in this case, these deterioration degrees may be complemented by each other.

With such a configuration, even when the deterioration degrees of the battery capacity voltage data to be integrated by the multiple data integration unit 13 are different, the difference between the deterioration degrees of the data to be integrated by the deterioration correction unit 61 can be reduced. Therefore, by analyzing the battery voltage curve created through the integration by the multiple data integration unit 13, and performing deterioration degree diagnosis, a more accurate deterioration degree can be estimated.

Next, a method for performing deterioration degree correction will be described with reference to FIG. 21 and FIG. 22.

FIG. 21 shows an example of a correlation between a time (days) and a capacity retention rate with a temperature of storage deterioration as a parameter. In FIG. 21, the horizontal axis indicates the 0.5th power of a storage time of the battery 20, and the vertical axis indicates the capacity retention rate of the battery 20.

FIG. 22 shows an example of a correlation between the number of cycles and the capacity retention rate with a temperature of cycle deterioration as a parameter. In FIG. 22, the horizontal axis indicates the number of cycles of the battery 20, and the vertical axis indicates the capacity retention rate of the battery 20. Here, the number of cycles of the battery 20 may be a charging/discharging accumulated capacity.

As for the deterioration model held by the deterioration correction unit 61, for example, for the storage deterioration in FIG. 21, the correlation between the number of days of storage and the temperature is used to correct the capacity retention rate.

Also, for the cycle deterioration in FIG. 22, the correlation between the number of cycles or the charging/discharging accumulated capacity and the temperature is used to correct the capacity retention rate.

The multiple data integration unit 13 may create a predetermined battery capacity voltage curve by correcting the deterioration degree by the deterioration correction unit 61 and integrating various battery capacity voltage data according to a predetermined capacity retention rate, and the deterioration degree diagnosis unit 14 may estimate a deterioration degree.

Alternatively, the multiple data integration unit 13 may be configured not to integrate the target battery capacity voltage data when the deterioration model is used by the deterioration correction unit 61 to determine the deterioration degree, and the deterioration degree of the battery capacity voltage data exceeds a predetermined threshold value for deterioration degrees.

As described above, the deterioration degree diagnosis device of Embodiment 4 is obtained by adding the deterioration correction unit to the multiple data integration unit of the deterioration degree diagnosis device of Embodiment 1.

Therefore, even when a charging operation as in an electric vehicle is a user-arbitrary operation, the deterioration degree diagnosis device of Embodiment 4 can accurately estimate the deterioration degree of the battery, and can further eliminate the influence of storage deterioration and cycle deterioration and accurately estimate the deterioration degree of the battery.

### Embodiment 5

A deterioration degree diagnosis device of Embodiment 5 is obtained by adding a deterioration suppression unit which suppresses deterioration of a battery, to the deterioration degree diagnosis device of Embodiment 1.

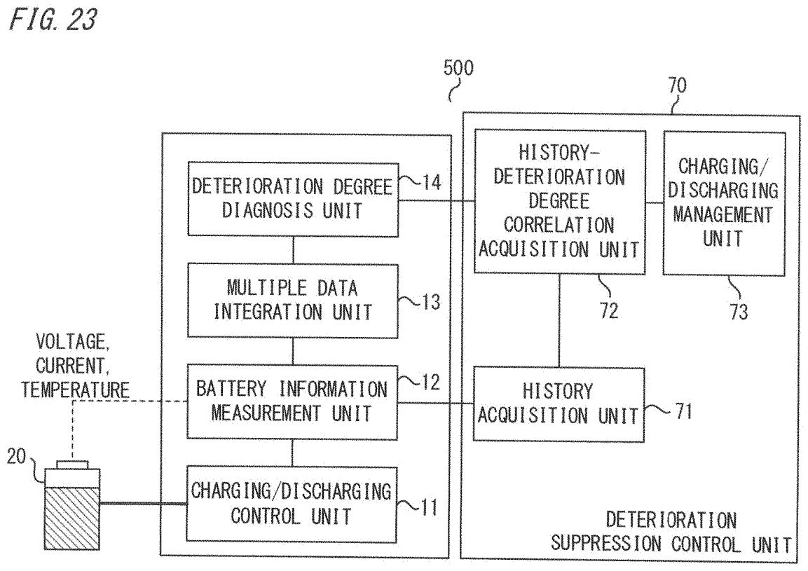

The deterioration degree diagnosis device of Embodiment 5 will be described, focusing on the differences from Embodiment 1, with reference to FIG. 23 which is a configuration diagram of the deterioration degree diagnosis device.

In the configuration diagram of Embodiment 5, parts that are the same as or correspond to those in Embodiment 1 are denoted by the same reference characters.

The entire configuration of a deterioration degree diagnosis device 500 of Embodiment 5 will be described with reference to FIG. 23.

The deterioration degree diagnosis device 500 includes a charging/discharging control unit 11 which has a function of charging a battery 20, a battery information measurement unit 12 which measures the current, the voltage, and the temperature of the battery 20, a multiple data integration unit 13 which integrates battery capacity voltage data obtained by the battery information measurement unit 12, and a deterioration degree diagnosis unit 14 which estimates a deterioration parameter and a deterioration degree of the battery 20. The deterioration degree diagnosis device 500 further includes a deterioration suppression unit 70 which suppresses deterioration of the battery 20.

The deterioration suppression unit 70 includes a battery usage history acquisition unit 71 which acquires a usage history of the battery 20, a battery usage history-deterioration degree correlation acquisition unit 72 which acquires a correlation between the usage history and information of a deterioration factor, and a charging/discharging management unit 73 which manages charging/discharging control of the battery 20 for suppressing deterioration of the battery 20.

In FIG. 23, the battery usage history acquisition unit is described as a history acquisition unit, and the battery usage history-deterioration degree correlation acquisition unit is described as a history-deterioration degree correlation acquisition unit.

The battery usage history-deterioration degree correlation acquisition unit 72 acquires a correlation between the usage history and the deterioration degree of the battery 20 and information of the deterioration factors for the positive electrode, the negative electrode, and Li ion consumption of the battery 20, all of which are obtained in each of the deterioration degree diagnosis devices 100 to 400 of Embodiments 1 to 4.

The charging/discharging management unit 73 manages charging and discharging of the battery 20 via the charging/discharging control unit 11 on the basis of the information acquired by the battery usage history-deterioration degree correlation acquisition unit 72, so as to suppress deterioration of the battery 20.

Moreover, the charging/discharging management unit 73 may perform management such that the battery 20 is rested on the basis of the present temperature, deterioration degree, and deterioration state of the battery 20.

In Embodiment 5, the deterioration degree diagnosis device 500 not only can show information about the deterioration degree of the battery 20 such as an appropriate battery replacement time to the user, but also can acquire a correlation between the deterioration factors for the positive electrode, the negative electrode, and Li ion consumption of the battery 20 and the usage history of the battery 20, analyze the present usage history and the deterioration factors, and perform charging/discharging management for suppressing deterioration of the battery 20.

As described above, the deterioration degree diagnosis device of Embodiment 5 is obtained by adding the deterioration suppression unit which suppresses deterioration of a battery, to the deterioration degree diagnosis device of Embodiment 1.

Therefore, even when a charging operation as in an electric vehicle is a user-arbitrary operation, the deterioration degree diagnosis device of Embodiment 5 can accurately estimate the deterioration degree of the battery, and can further perform charging/discharging management for suppressing deterioration of the battery.

Here, the hardware configurations of the deterioration degree diagnosis devices 100 to 500 according to Embodiments 1 to 5 will be described. Each function unit of the deterioration degree diagnosis devices 100 to 500 is realized by a processing circuit described below. This processing circuit may be realized by dedicated hardware or general-purpose hardware.

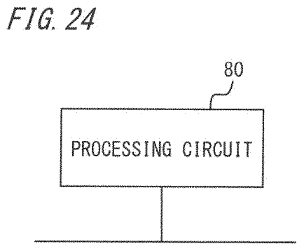

FIG. 24 shows the configuration of the processing circuit when the processing circuit is realized by dedicated hardware.

A processing circuit 80 in FIG. 24 is a single circuit, a composite circuit, a programmed processor, a parallel programmed processor, an application specific integrated circuit (ASIC), a field programmable gate array (FPGA), or a combination thereof.

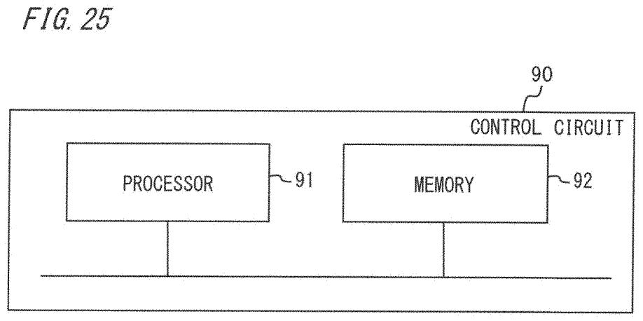

FIG. 25 shows the configuration of the processing circuit when the processing circuit is realized by general-purpose hardware.

As shown in FIG. 25, a control circuit 90 includes a processor 91 and a memory 92.

The processor 91 is a central processing unit (CPU), and is called a central processor, a processing device, an arithmetic device, a microprocessor, a microcomputer, a digital signal processor (DSP), or the like.

The memory 92 is, for example, a non-volatile or volatile semiconductor memory such as a random access memory (RAM), a read only memory (ROM), a flash memory, an erasable programmable ROM (EPROM), or an electrically EPROM (registered trademark) (EEPROM), a magnetic disk, a flexible disk, an optical disk, a compact disk, a mini disk, a digital versatile disk (DVD).

When the processing circuit is realized by the control circuit 90 which is general-purpose hardware, the processing circuit is realized by the processor 91 reading and executing a program corresponding to the processing of each component stored in the memory 92. In addition, the memory 92 is also used as a temporary memory in each process executed by the processor 91.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### INDUSTRIAL APPLICABILITY

The present disclosure allows a deterioration degree of a battery to be accurately estimated even when a charging operation as in an electric vehicle is a user-arbitrary operation, and therefore can be widely applied to deterioration degree diagnosis devices.

### DESCRIPTION OF THE REFERENCE CHARACTERS

11 charging/discharging control unit
12 battery information measurement unit
13 multiple data integration unit
14 deterioration degree diagnosis unit
20 battery
31 data storage unit
32 data integration unit
41 temperature data conversion unit
42 reaction distribution correction unit
51 hysteresis correction unit
61 deterioration correction unit
70 deterioration suppression unit
71 battery usage history acquisition unit
72 battery usage history-deterioration degree correlation acquisition unit
73 charging/discharging management unit
80 processing circuit
90 control circuit
91 processor
92 memory
100, 200, 300, 400, 500 deterioration degree diagnosis device
R1, R2, R3 electrolyte resistance
R4, R5, R6 diffusion resistance
C4, C5, C6 capacitance
OCV1, OCV2, OCV3 model battery open circuit voltage

1. A deterioration degree diagnosis device comprising:
a charging/discharging controlling circuitry configured to control charging or discharging of a battery;
a battery information measurement circuitry configured to measure a voltage and a current of the battery and measure a capacity and voltage transition during charging or discharging;
a multiple data integration circuitry configured to integrate battery capacity voltage data in at least two different sections measured by the battery information measurement circuitry, and create a battery capacity voltage curve; and
a deterioration degree diagnosis circuitry configured to estimate a deterioration degree of the battery on the basis of the battery capacity voltage curve, wherein
when there are no two peaks related to the negative electrode or there is no one peak related to the positive electrode in the derivative curve of the battery capacity voltage curve integrated by the multiple data integration circuitry,
the multiple data integration circuitry adds the battery capacity voltage data to be integrated.

2. The deterioration degree diagnosis device according to claim 1, wherein the deterioration degree diagnosis circuitry analyzes a derivative curve of the battery capacity voltage curve, and identities deterioration factors based on a positive electrode and a negative electrode of the battery, and Li ion consumption when the battery is a lithium ion battery.

3. The deterioration degree diagnosis device according to claim 1, wherein the battery capacity voltage curve integrated by the multiple data integration circuitry has at least two peaks related to the negative electrode, in the derivative curve thereof.

4. The deterioration degree diagnosis device according to claim 1, wherein the battery capacity voltage curve integrated by the multiple data integration circuitry has at least one peak related to the positive electrode, in the derivative curve thereof.

5. (canceled)

6. A deterioration degree diagnosis device comprising:
a charging/discharging controlling circuitry configured to control charging or discharging, of a battery;
a battery information measurement circuitry configured to measure a voltage and a current of the battery and measure a capacity and voltage transition during charging or discharging;
a multiple data integration circuitry configured to integrate battery capacity-voltage data in at least two different sections measured by the battery information measurement circuitry, and create a battery capacity voltage curve; and
a deterioration degree diagnosis circuitry configured to estimate a deterioration degree of the battery on the basis of the battery capacity voltage curve,
wherein the multiple data integration circuitry integrates derivative curves of a plurality of the battery capacity voltage curves.

7. The deterioration degree diagnosis device according to claim 1, wherein
the battery information measurement circuitry further measures a temperature of the battery, and
the multiple data integration circuitry includes a temperature data conversion circuitry configured to correct a difference in the temperature between at least the two battery capacity voltage data in which the temperatures measured by the battery information measurement circuitry are different from each other, on the basis of a temperature-resistance value correlation, and wherein the temperature data conversion circuitry includes a reaction distribution correction circuitry configured to correct a reaction distribution inside a battery electrode, for at least the two battery capacity voltage data in which the temperatures are different from each other.

8. (canceled)

9. The deterioration degree diagnosis device according to claim 1, wherein, from the battery capacity voltage data having a hysteresis in which open circuit voltages during charging and discharging of the battery are different, the multiple data integration circuitry selects data on which there is no influence of the hysteresis, on the basis of analysis of a derivative curve.

10. The deterioration degree diagnosis device according to claim 1, wherein the multiple data integration circuitry includes a hysteresis correction circuitry configured to correct, for the battery capacity voltage data having a hysteresis in which open circuit voltages during charging and discharging of the battery are different, a difference due to the hysteresis on the basis of a hysteresis model.

11. A deterioration degree diagnosis device comprising:
a charging/discharging controlling circuitry configured to control charging or discharging of a battery;
a battery information measurement circuitry configured to measure a voltage and a current of the battery and measure a capacity and voltage transition during charging or discharging;
a multiple data integration circuitry configured to integrate battery capacity voltage data in at least two different sections measured by the battery information measurement circuitry, and create a battery capacity voltage curve; and
a deterioration degree diagnosis circuitry configured to estimate a deterioration degree of the battery on the basis of the battery capacity voltage curve,
wherein the multiple data integration circuitry selects and integrates the battery capacity voltage data between which a difference in deterioration degree is within a threshold value, out of the battery capacity voltage data in at least two different sections.

12. The deterioration degree diagnosis device according to claim 1, wherein
the multiple data integration circuitry Mu includes a deterioration correction circuitry, and
when the deterioration degrees of the battery capacity voltage data in at least two different sections are different,
the deterioration correction circuitry performs either one of or both calculation of a storage deterioration degree based on a correlation between a temperature, a time, and a storage deterioration degree for the battery capacity voltage data in at least two different sections, and calculation of a cycle deterioration degree based on a correlation between a temperature, a charging/discharging accumulated amount, a number of cycles, and a cycle deterioration degree, and
the deterioration correction circuitry corrects a difference between data due to storage deterioration or cycle deterioration.

13. The deterioration degree diagnosis device according to claim 1, further comprising a deterioration suppression controlling circuitry configured to perform charging/discharging control for suppressing deterioration of the battery, wherein
the deterioration suppression controlling circuitry includes:
a battery usage history acquisition circuitry configured to acquire a usage history of the battery;
a battery usage history-deterioration degree correlation acquisition circuitry configured to acquire a correlation between the deterioration degree acquired by the deterioration degree diagnosis circuitry and the battery usage history acquired by the battery usage history acquisition circuitry; and
a charging/discharging management circuitry configured to manage charging/discharging of the battery on the basis of the correlation acquired by the battery usage history-deterioration degree correlation acquisition circuitry.

14. The deterioration degree diagnosis device according to claim 1, wherein
the multiple data integration circuit integrates the battery capacity voltage data in at least two different sections in different charging or discharging cycles measured by the battery information measurement circuit, and creates the battery capacity voltage curve.

15. The deterioration degree diagnosis device according to claim 1, wherein
the multiple data integration circuit stores the battery capacity voltage data measured by the battery information measurement circuit, integrates the stored battery capacity voltage data and the stored battery capacity voltage data in a different section, and creates the battery capacity voltage curve.

16. The deterioration degree diagnosis device according to claim 6, wherein the battery capacity voltage curve integrated by the multiple data integration circuitry has at least one peak related to the positive electrode, in the derivative curve thereof.

17. The deterioration degree diagnosis device according to claim 6, wherein the battery capacity voltage curve integrated by the multiple data integration circuitry has at least two peaks related to the negative electrode, in the derivative curve thereof.

18. The deterioration degree diagnosis device according to claim 6, wherein
the multiple data integration circuit integrates the battery capacity voltage data in at least two different sections in different charging or discharging cycles measured by the battery information measurement circuit, and creates the battery capacity voltage curve.

19. The deterioration degree diagnosis device according to claim 6, wherein
the multiple data integration circuit stores the battery capacity voltage data measured by the battery information measurement circuit, integrates the stored battery capacity voltage data and the stored battery capacity voltage data in a different section and creates the battery capacity voltage curve.

20. The deterioration degree diagnosis device according to claim 11, wherein the battery capacity voltage curve integrated by the multiple data integration circuitry has at least one peak related to the positive electrode, in the derivative curve thereof.

21. The deterioration degree diagnosis device according to claim 11, wherein the battery capacity voltage curve integrated by the multiple data integration circuitry has at least two peaks related to the negative electrode, in the derivative curve thereof.

22. The deterioration degree diagnosis device according to claim 11, wherein
the multiple data integration circuit integrates the battery capacity voltage data in at least two different sections in different charging or discharging cycles measured by the battery information measurement circuit, and creates the battery capacity voltage curve.
